(19) United States
(12) Patent Application Publication
(10) Pub. No.: US 2015/0115319 A1
(43) Pub. Date: Apr. 30, 2015

(54) PLANAR AVALANCHE PHOTODIODE

(71) Applicant: PICOMETRIX, LLC, ANN ARBOR, MI (US)

(72) Inventor: Barry Levine, Livingston, NJ (US)

(21) Appl. No.: 14/400,478

(22) PCT Filed: May 17, 2013
(86) PCT No.: PCT/US13/41536

§ 371 Date: Nov. 11, 2014

Related U.S. Application Data
(60) Provisional application No. 61/648,401, filed on May 17, 2012.

(51) Int. Cl. H01L 31/107; H01L 31/0304

(52) U.S. Cl. CPC H01L 31/1075; H01L 31/03046; H01L 31/03042
USPC 257/186

(57) ABSTRACT

An avalanche photodiode includes a first semiconductor layer, a multiplication layer, a charge control layer, a second semiconductor layer, a graded absorption layer, a blocking layer and a second contact layer. The multiplication layer is located between the charge control layer and the first semiconductor layer. The charge control layer is located between the second semiconductor layer and the multiplication layer. The second semiconductor layer is located between the charge control later and the graded absorption layer. The graded absorption layer is located between the second semiconductor layer and the blocking layer.

### CROSS REFERENCE TO RELATED PATENT APPLICATION

This application claims priority to U.S. Provisional Patent Application 61/648,401, which is hereby incorporated by reference in its entirety.

### BACKGROUND

The present invention relates to photodetectors. More specifically, the present invention relates to avalanche photodiodes (“APDs”).

Owing to the known interaction between photons and electrons, advances have been made in the field of photodetectors in recent years, particularly in those photodetectors that utilize semiconductor materials. One type of semiconductor-based photodetector known as an avalanche photodiode includes a number of semiconductive materials that serve different purposes such as absorption and multiplication.

The avalanche photodiode structure provides a large gain through the action of excited charge carriers that produce large numbers of electron-hole pairs in the multiplication layer. In order to prevent tunneling in the absorption layer, the electric field is regulated within the avalanche photodiode itself, such that the electric field in the multiplication layer is significantly higher than that in the absorption layer.

A particular type of avalanche photodiode know as a mesa avalanche photodiode exposes high field p-n junctions and large numbers of exposed surface and interface states that make it difficult to passivate using a layer of insulating material. Therefore, conventional InP/InGaAs avalanche photodiodes use diffused structures which bury the p-n junction. However, these InP avalanche photodiodes require extremely accurate diffusion control of both the depth and the doping density of the p-type semiconductor regions as well as accurate control of the n-doped region into which this diffusion occurs. This critical doping control is essential, since the diffusion controls the placement of the p-n junction, the magnitude of the electric field in the multiplication region, the length of the avalanche region, as well as the total charge in the charge control layer which determines the values of the electric fields in both the high field InP avalanche region, which must be large enough to produce multiplication, as well as the low field InGaAs absorbing region, which must be small enough to avoid tunneling. In addition, accurately placed diffused or implanted guards rings are used in this type of arrangement, to avoid avalanche breakdown at the edges of the diffused p-n junction. This combination of guard rings and critically controlled diffusions increases the capacitance, lowers the bandwidth, and reduces the yield, thus increasing the cost of these APDs.

For ultrahigh speed performance detectors, InAlAs can be used as the avalanche layer rather than InP, since the higher bandgap reduces tunneling and thus allows thinner avalanche regions to be used leading to higher speeds and higher performance receivers. However, a diffused structure is even more difficult to achieve in InAlAs since the larger electron avalanche coefficient (relative to the holes) makes it desirable to multiply the electrons rather than the holes as in standard InP based APDs. Moreover, simply reversing the standard p-doped diffused structure is not sufficient, since n-dopants do not diffuse fast enough.

### SUMMARY

In overcoming the drawbacks of the prior art, the applicant has discovered that since PIN detectors can be easily passivated with proper surface preparation and covered with BCB, to etch the small area p+ InGaAs absorption region on top of the large area undoped InGaAs absorption layer, and passivate it with BCB like a PIN.

An avalanche photo diode includes a first semiconductor layer, a multiplication layer, a charge control layer, a second semiconductor layer, a graded absorption layer, and a blocking layer. The multiplication layer is located between the first semiconductor layer and the charge control layer. The second semiconductor layer is located between the charge control layer and the graded absorption layer. The blocking layer is located adjacent to the graded absorption layer, opposite of the second semiconductor layer.

In another embodiment, the graded absorption layer may be etched to find a small area absorption region on top of the second semiconductor layer. The avalanche diode may also include a first contact adjacent to the first semiconductor layer and a second contact adjacent to the small area absorption region on top of the second semiconductor layer. Additionally, the portion of the avalanche photodiode may be passivated with a passivation structure, such as BCB.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a cross-sectional view of a planar avalanche photodiode in accordance with the present invention; and

FIG. 2 is a cross-sectional view of an alternative planar avalanche photodiode in accordance with the present invention.

### DETAILED DESCRIPTION

U.S. Pat. No. 7,348,608, which is hereby incorporated by reference in its entirety, contained several innovations including that the multiplication layer is buried below the absorption layer; the p+ charge control layer extends across the entire large outer mesa but does not increase the capacitance or reduce the bandwidth at the operating bias due to the concentration of the electric field under the small mini mesa; the absorption layer is grown above the charge control and above the multiplication layers; that all these layers have the full large area of the outer mesa; and that the small top p+ mini mesa determines the active area and capacitance and bandwidth.

In the U.S. Pat. No. 7,348,608, which is hereby incorporated by reference in its entirety, the InGaAs absorption layer is undoped and thus depleted at the operating bias. The charge control layer and the multiplication layers are also fully depleted at the operating bias. Thus, the small top p+ mini mesa controls the electric field which is only large directly under this mini mesa. Thus the capacitance is small since it is determined by the area of the small mini mesa.

The electric field across the depleted absorption layer collects the electrons and holes, and determines their transit time, which contributes to the total transit time across the entire device and thus determines the overall response speed.

U.S. Pat. No. 7,078,741, which is hereby incorporated by reference in its entirety, discloses a graded p+ doping in the InGaAs absorption layer to increase the responsivity without significantly increasing the transit time or reducing the bandwidth. However, this p+ doping layer cannot be simply grown on top of the existing APD structure with the same large outer mesa size as the undoped InGaAs absorption layer, since it would not be depleted and the large area p+ InGaAs layer would create a large capacitance together with the large n+ bottom layer. That is, the additional p+ layer must be the same small size as the active region of the APD in order to have low capacitance and high bandwidth.

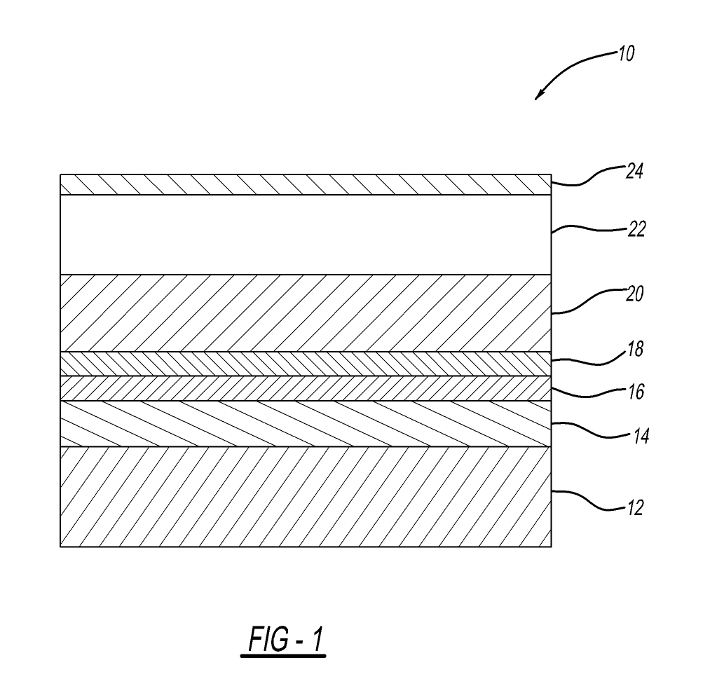

Referring to FIG. 1, an avalanche photodiode 10 is shown. As its primary components, the avalanche photodiode 10 includes a first semiconductor layer 12, a multiplication layer 14, a charge control layer 16, a digital grade layer 18, a second semiconductor layer 20, a graded absorption layer 22, and a blocking layer 24. As shown in FIG. 1, the multiplication layer 14 is located between the charge control layer 16 and the first semiconductor layer 12. The digital grade layer 18 is located between the charge control layer 16 and a second semiconductor layer 20. On top of the second semiconductor layer 20 is a graded absorption layer 22. On top of the graded absorption layer 22, is the blocking layer 22.

The first semiconductor layer 12 may be an n type semiconductor and may be selected from a group including tertiary semiconductors, or group III-V semiconductors. Accordingly, the first semiconductor layer 12 is either two elements from group III combined with one element from group V or the converse, two elements from group V combined with one element from group III. A table of representative groups of the periodic table is shown below.

| GROUP II | GROUP III | GROUP IV | GROUP V |
|---|---|---|---|
| Zinc (Zn) | Aluminum (Al) | Silicon (Si) | Phosphorus (P) |
| Cadmium (Cd) | Gallium (Ga) | Germanium (Ge) | Arsenic (As) |
| Mercury (Hg) | Indium (In) | | Antimony (Sb) |

In certain embodiments, the first semiconductor layer 12 is InAlAs. However, it is understood that the first semiconductor layer 12 may be any binary or tertiary semiconductor that provides the bandgap for optimized operation of the avalanche photodiode 10. The semiconductor multiplication layer 14 may also selected from a group including tertiary semiconductors, or group III-V semiconductors. In the preferred embodiment, the semiconductor multiplication layer 14 is InAlAs.

The graded absorption layer 22 is also selected from a group including tertiary semiconductors, or group III-V semiconductors. In the preferred embodiment, the graded absorption layer 22 is InGaAs. However, it is understood that both the graded absorption layer 22 and the semiconductor multiplication layer 14 may be any binary or tertiary semiconductor that provides the bandgap for optimized operation of the planar avalanche photodiode 10.

The second semiconductor layer 20 may also selected from a group including tertiary semiconductors, or group III-V semiconductors. As before, the second semiconductor layer 20 is either two elements from group III combined with one element from group V or the converse, two elements from group V combined with one element from group III. In the preferred embodiment, the second semiconductor layer 20 is InAlAs. However, it is understood that the second semiconductor layer 20 may be any binary or tertiary semiconductor that provides the bandgap for optimized operation of the avalanche photodiode 10.

A feature of the planar avalanche photodiode 10 is that all the critical layer thicknesses and doping concentrations are regulated in the initial crystal growth, and thus are under control, such that they can be reproducibly grown and are uniform over the entire wafer. Accordingly, difficulties associated with process control during fabrication, particularly those related to the diffusion step, are not manifest.

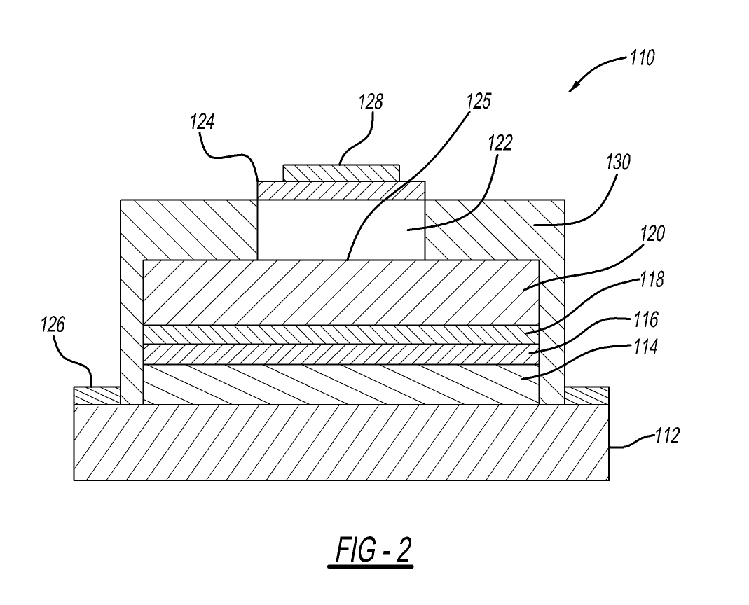

Referring to FIG. 2, a second embodiment of the avalanche photodiode 110 is shown. It is first noted that like reference numerals have been utilized to refer to like components. For example, first semiconductor layer 112 of FIG. 2 is similar to first semiconductor layer 12 of FIG. 1. As in FIG. 1, the avalanche photodiode 110 includes a first semiconductor layer 112, a multiplication layer 114, a charge control layer 116, a digital grade layer 118, a second semiconductor layer 120, a graded absorption layer 122, and a blocking layer 124. In this embodiment, the avalanche photodiode 110 has been etched. More specifically, the graded absorption layer 122 has been etched to define a small area absorption region 125 on top of the second semiconductor layer 120. Further, the avalanche photodiode 110 includes a first contact 126 adjacent to the first semiconductor layer 112 and a second contact 128 adjacent to the blocking layer 124. The avalanche photodiode 110 may also have at least a portion being passivated with a passivation structure 130. The passivation structure may be made a BCB.

FIGS. 1 and 2 show that the charge control layer 16 or 116, which can be grown using carbon or Be as the p-dopant, extends across the entire isolation mesa. In spite of the large area of the p-n junction in this isolation mesa, the capacitance above punch-through is not substantially increased. This occurs because the device capacitance is (after charge punch-through and depletion) determined mainly by the area of the small diffused region (photodiode 10) or etched p+ region (photodiode 110) and not the isolation mesa, thus leading to a low capacitance, high speed APD.

The photodetectors described above can be implemented as waveguide photodetectors or as single photon detectors. The photodetectors may have an integrated lens for improved light collection.

The forgoing and other implementations are within the scope of the following claims. For example, all n and p doped semiconductors may be interchanged. That is the n and p doping may be reversed to provide a top mini mesa of n type semiconductor and a lower contact of a p type.

What is claimed here is:

1. An avalanche photodiode comprising:
a first semiconductor layer layer;
a multiplication layer adjacent to the first semiconductor layer;
a charge control layer adjacent to the multiplication layer, opposite of the first semiconductor layer;
a second semiconductor layer, the second semiconductor layer being low doped or not intentionally doped, the second semiconductor layer being adjacent to the charge control layer, opposite of the multiplication layer;
a graded absorption layer being adjacent to the semiconductor layer, opposite of the second semiconductor layer; and
a blocking layer located adjacent to the graded absorption layer, opposite of the second semiconductor layer.

2. The avalanche photodiode of claim 1, further comprising a digital grade layer located between the charge control layer and the second semiconductor layer.

3. The avalanche photodiode of claim 1, wherein the first semiconductor layer is made of indium phosphide.

4. The avalanche photodiode of claim 3, where the first semiconductor layer is doped n+.

5. The avalanche photodiode of claim 1, wherein the multiplication layer is made of indium aluminum arsenide.

6. The avalanche photodiode of claim 1, wherein the graded absorption layer is made of indium gallium arsenide.

7. The avalanche photodiode of claim 1, wherein the graded absorption layer is doped p+.

8. The avalanche diode of claim 1, further comprising a first contact adjacent to the first semiconductor layer

9. The avalanche photodiode of claim 9, wherein the graded absorption layer is etched to define a small area absorption region on top of the second semiconductor layer.

10. The avalanche diode of claim 9, further comprising a second contact adjacent to the small area absorption region on top of the second semiconductor layer.

11. The avalanche photodiode of claim 10, wherein at least a portion of the avalanche photodiode is passivated with a passivation structure.

12. The avalanche photodiode of claim 11, wherein the passivation structure is made of benzocyclobutene.
